(19) United States
(12) Patent Application Publication
(10) Pub. No.: US 2014/0332874 A1
(43) Pub. Date: Nov. 13, 2014

(54) SEMICONDUCTOR DEVICES

(71) Applicants: Jeonggil LEE, Hwaseong-si (KR); Tai-Soo LIM, Seoul (KR); HyunSeok LIM, Seo-gu (KR); Kihyun YUN, Seoul (KR); Hauk HAN, Hwaseong-si (KR); Myoungbum LEE, Seoul (KR)

(72) Inventors: Jeonggil LEE, Hwaseong-si (KR); Tai-Soo LIM, Seoul (KR); HyunSeok LIM, Seo-gu (KR); Kihyun YUN, Seoul (KR); Hauk HAN, Hwaseong-si (KR); Myoungbum LEE, Seoul (KR)

(21) Appl. No.: 14/338,774

(22) Filed: Jul. 23, 2014

Related U.S. Application Data
(62) Division of application No. 13/783,590, filed on Mar. 4, 2013.

(30) Foreign Application Priority Data
Apr. 13, 2012 (KR) 10-2012-0038267

(51) Int. Cl. H01L 29/788; H01L 29/51; H01L 29/49

(52) U.S. Cl. CPC H01L 29/788; H01L 29/4925; H01L 29/4958; H01L 29/517; H01L 29/518
USPC 257/316

(57) ABSTRACT

A semiconductor device includes a substrate, a first poly-silicon pattern on the substrate, a metal pattern on the first poly-silicon pattern, and an interface layer between the first poly-silicon pattern and the metal pattern. The interface layer may include at least one selected from the group of a metal-silicon oxynitride layer, a metal-silicon oxide layer, and a metal-silicon nitride layer.

### CROSS-REFERENCE TO RELATED APPLICATIONS

This is a divisional application based on pending application Ser. No. 13/783,590 filed Mar. 4, 2013, the entire contents of which is hereby incorporated by reference.

The present application claims priority under 35 U.S.C. §119 to Korean Patent Application No. 10-2012-0038267, filed on Apr. 13, 2012, in the Korean Intellectual Property Office, and entitled: “Semiconductor Devices and Methods for Fabricating the Same,” which is incorporated by reference herein in its entirety.

### BACKGROUND

1. Field

Embodiments relate to semiconductor devices and methods for fabricating the same.

2. Description of the Related Art

Data storing patterns having a memory function and word lines controlling data storing states thereof may be disposed in a cell array region of a non-volatile memory device. Additionally, the non-volatile memory device may include a peripheral circuit for controlling the word lines. The peripheral circuit may include, e.g., transistors of a metal-oxide-semiconductor field-effect transistor (MOSFET) structure.

### SUMMARY

Embodiments are directed to a semiconductor device including a substrate, a first poly-silicon pattern on the substrate, a metal pattern on the first poly-silicon pattern, and an interface layer between the first poly-silicon pattern and the metal pattern. The interface layer may include at least one selected from the group of a metal-silicon oxynitride layer, a metal-silicon oxide layer, and a metal-silicon nitride layer.

A metal included in the interface layer may be the same as a metal constituting the metal pattern.

A crystal grain size of the metal pattern may be equal to greater than about 200 nm, the metal pattern may have a body centered cubic structure, and a ratio of a surface density of a (110) plane to a surface density of a (200) plane in the body centered cubic structure may be equal to or greater than about 200.

The device may further include a second poly-silicon pattern under the first poly-silicon pattern, a blocking insulating layer between the second poly-silicon pattern and the first poly-silicon pattern, and a tunnel insulating layer between the second poly-silicon pattern and the substrate.

The metal pattern may penetrate at least the first poly-silicon pattern and the blocking insulating layer, such that the metal pattern may be adjacent to the second poly-silicon pattern, and the interface layer may be between a top surface of the first poly-silicon pattern and the metal pattern, and between a top surface of the second poly-silicon pattern and the metal pattern.

The device may further include an amorphous layer between a sidewall of the first poly-silicon pattern and the metal pattern, and the amorphous layer may not be doped with the metal included in the interface layer.

A width of the amorphous layer may be greater than a thickness of the interface layer.

The amorphous layer may include at least one selected from the group of a silicon nitride layer, a silicon oxide layer, and a silicon oxynitride layer.

The device may further include metal silicide particles adjacent to a top surface of the first poly-silicon pattern and to a top surface of the second poly-silicon pattern under the interface layer, and the metal silicide particles may be discontinuous.

Embodiments are also directed to a method for fabricating a semiconductor device, the method including forming a first poly-silicon layer on a substrate, forming an amorphous layer on the first poly-silicon layer, providing a metal into the amorphous layer to form an interface layer, forming a metal layer on the interface layer, the metal layer being made of the metal, and patterning the metal layer, the interface layer, and the first poly-silicon layer.

The method may further include performing a thermal treatment process after forming the metal layer, and the thermal treatment process may combine the metal included in the interface layer with an amorphous material in the interface layer.

Providing the metal into the amorphous layer may include converting a metal element into a plasma state, and applying a bias to permeate the metal element in the plasma state into the amorphous layer.

Forming the amorphous layer may include forming a double layer of a silicon oxide layer and a silicon nitride layer, the interface layer may be formed of a metal-silicon oxynitride layer, and the double layer in the amorphous layer may be converted to a single layer of the metal-silicon oxynitride layer by permeating the metal element in the plasma state into the amorphous layer.

A thickness of each of the silicon oxide layer and the silicon nitride may be within a range of about 1 Å to about 30 Å.

The method may further include sequentially forming a tunnel insulating layer, a second poly-silicon layer, and a blocking insulating layer on the substrate before forming the first poly-silicon layer, and patterning at least portions of the first poly-silicon layer and the blocking insulating layer to expose the second poly-silicon layer before forming the amorphous layer. A portion of the amorphous layer may extend to cover sidewalls of the patterned first poly-silicon layer and the patterned blocking insulating layer, and the portion of the amorphous layer covering the sidewalls may not include the metal.

Embodiments are also directed to a semiconductor device including a substrate having a first region and a second region, a first lower poly-silicon pattern on the first region of the substrate, a first blocking insulating layer on the first lower poly-silicon pattern, a first upper poly-silicon pattern on the first blocking insulating layer, and a first interface layer on the first upper poly-silicon pattern. The first interface layer may include at least one selected from the group of a metal-silicon oxynitride layer, a metal-silicon oxide layer, and a metal-silicon nitride layer. The semiconductor device may further include a second lower poly-silicon pattern on the second region of the substrate, a second blocking insulating layer on the second lower poly-silicon pattern, a second upper poly-silicon pattern on the second blocking insulating layer, and a second interface layer on the second lower poly-silicon pattern and the second upper poly-silicon pattern. The second interface layer may include at least one selected from the group of the metal-silicon oxynitride layer, the metal-silicon oxide layer, and the metal-silicon nitride layer. The first upper poly-silicon pattern may be between all portions of the first interface layer and the first lower semiconductor pattern, and the second interface layer may include a first portion and a second portion. The first portion of the second interface layer may be on the second upper poly-silicon pattern, and the second portion of the second interface layer may be directly on the second lower poly-silicon pattern.

The first lower poly-silicon pattern, the first blocking insulating layer, the first upper poly-silicon pattern, and the first interface layer on the first region may be part of a memory cell, and the second lower poly-silicon pattern, the second blocking insulating layer, the second upper poly-silicon patter, and the second interface layer on the second region may be part of a non-memory cell.

The device may further include an amorphous layer in the second region, the amorphous layer may be between the first portion of the second interface layer and the second portion of the second interface layer, and the amorphous layer may not include the metal-silicon oxynitride layer, the metal-silicon oxide layer, or the metal-silicon nitride layer.

The amorphous layer may cover a sidewall of the second upper poly-silicon pattern and the second blocking insulating layer, and a bottom surface of the second portion of the second interface layer may be below a top surface of the second lower poly-silicon pattern.

The device may further include a first metal layer covering the first interface layer, and a second metal layer covering the first portion of the second interface layer, the second portion of the second interface layer, and the amorphous layer.

### BRIEF DESCRIPTION OF THE DRAWINGS

Features will become apparent to those of skill in the art by describing in detail exemplary embodiments with reference to the attached drawings in which:

FIG. 1 illustrates a cross-sectional view of a semiconductor device according to an embodiment;

FIG. 2A illustrates a cross-sectional view of a semiconductor device according to an embodiment;

FIGS. 2B and 2C illustrate enlarged views of a portion P1 and a portion P2 of FIG. 2A, respectively;

FIGS. 3 to 9 illustrate cross-sectional views of exemplary stages in a method of fabricating the semiconductor device of FIG. 2A according to an embodiment;

FIG. 10 illustrates a cross-sectional view of a non-volatile memory device according to an embodiment;

FIG. 11 illustrates a schematic block diagram of an exemplary memory system including a semiconductor device according to an embodiment;

FIG. 12 illustrates a schematic block diagram of an exemplary memory card including a semiconductor device according to an embodiment; and

FIG. 13 illustrates a schematic block diagram of an exemplary information processing system including a semiconductor device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Additionally, the embodiments in the detailed description will be described with sectional views as ideal exemplary views of the embodiments. Accordingly, shapes of the exemplary views may be modified according to manufacturing techniques and/or allowable errors. Therefore, the embodiments are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the embodiments.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of the embodiments.

It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. In contrast, the term “directly” means that there are no intervening elements. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Like reference numerals refer to like elements throughout.

The terminology used herein is for the purpose of describing particular embodiments only and is not intended to limit the embodiments. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the embodiments. Exemplary embodiments explained and illustrated herein include their complementary counterparts.

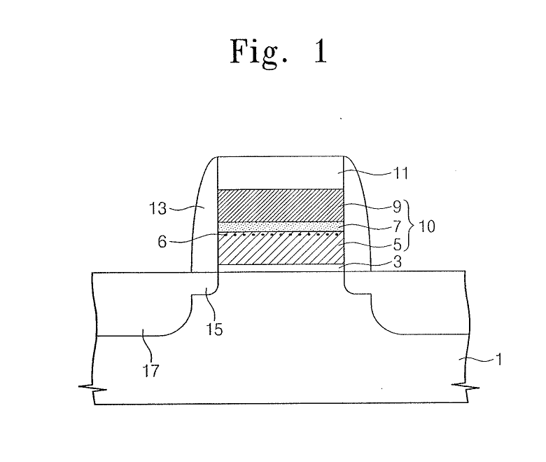

FIG. 1 illustrates a cross-sectional view of a semiconductor device according to an embodiment.

Referring to FIG. 1, a semiconductor device may include a gate insulating layer 3 and a gate electrode 10 which may be sequentially stacked on a substrate 1. The gate electrode 10 may include a poly-silicon pattern 5, an interface layer 7, and a metal pattern 9, which may be sequentially stacked. The poly-silicon pattern 5 may be doped with N-type dopants or P-type dopants.

The interface layer 7 may be formed of at least one of a metal silicon oxide layer, a metal silicon nitride layer, and a metal silicon oxynitride layer. The interface layer 7 may be formed by providing a metal into an amorphous layer such as a silicon oxide layer, a silicon nitride layer, and/or a silicon oxynitride layer. The metal in the interface layer 7 may be the same as a metal constituting the metal pattern 9. A thickness of the interface layer 7 may be within a range of about 1 Å to about 100 Å, or about 5 Å to about 40 Å.

The metal pattern 9 may include a metal such as, e.g., tungsten, aluminum, titanium, nickel, cobalt, copper, and/or the like. Since the metal pattern 9 is disposed on the interface layer 7 (which may be an amorphous layer), a crystal grain size of the metal pattern 9 may be relatively increased. In more detail, the crystal grain size of the metal pattern 9 may be equal to or greater than about 200 nm, or equal to or greater than 350 nm. The metal pattern 9 may have a body centered cubic structure. A ratio of a surface density of a (110) plane to a surface density of a (200) plane [(110)/(200)] may be equal to or greater than 200, or equal to or greater than 240 in the body centered cubic structure of the metal pattern 9. As described above, the crystal grain size of the metal pattern 9 may be increased, and thus a resistivity of the metal pattern 9 may decrease. Thus, signal transmission speed of the semiconductor device including the gate electrode 10 illustrated in FIG. 1 may be improved.

In an embodiment, the metal pattern 9 may be formed of a pure tungsten layer and the interface layer 7 may be formed of at least one of a tungsten-silicon oxide layer, a tungsten-silicon nitride layer, and a tungsten-silicon oxynitride layer.

The interface layer 7 may function as a diffusion preventing layer that substantially prevents and/or reduces the possibility of a reaction between the metal pattern 9 and the poly-silicon pattern 5. Additionally, the interface layer 7 may include a metal, and thus the interface layer 7 may function as an ohmic layer between the poly-silicon pattern 5 and the metal pattern 9. Thus, it may be possible to reduce an interface resistance between the metal pattern 9 and the poly-silicon pattern 5. As a result, the signal transmission speed of the semiconductor device may be improved.

Discontinuous metal silicide particles 6 may be disposed under the interface layer 7 and may be adjacent to a top surface of the poly-silicon pattern 5 (e.g., disposed in the polysilicon pattern 5). The metal silicide particles 6 may be a plurality of isolated island-shapes which may not be connected to each other.

A capping pattern 11 may be disposed on a top surface of the gate electrode 10, and a spacer 13 may cover a sidewall (e.g., both sidewalls) of the gate electrode 10. A low concentration dopant injection region 15 and a high concentration dopant injection region 17 may be disposed in the substrate.

The gate electrode 10 may include the interface layer 7 and may be applied to a control gate (or a word line) of a memory cell disposed in a cell array region. In this case, even though not shown in the drawings, the gate insulating layer 3 may include a tunnel insulating layer, a charge trap layer, and/or a blocking insulating layer, which may be sequentially stacked. According to another exemplary embodiment, a floating gate pattern and a blocking insulating layer may be disposed between the gate insulating layer 3 and the poly-silicon pattern 5. In an embodiment, the gate electrode 10 may include the interface layer 7 and may be applied to a gate electrode of a non-memory cell disposed in a peripheral circuit region.

Deterioration of a diffusion preventing property and an interface contact resistance property (or a property of an ohmic layer) may be substantially prevented (and/or the possibility thereof may be substantially reduced) in the gate electrode 10 according to an embodiment, e.g., due to the interface layer 7. The metal pattern 9 may have an increased crystal grain size, and thus the metal pattern 9 may have a reduced resistance of, e.g., about 9 μΩ/cm when a thickness of the metal pattern 9 is equal to or greater than about 40 nm.

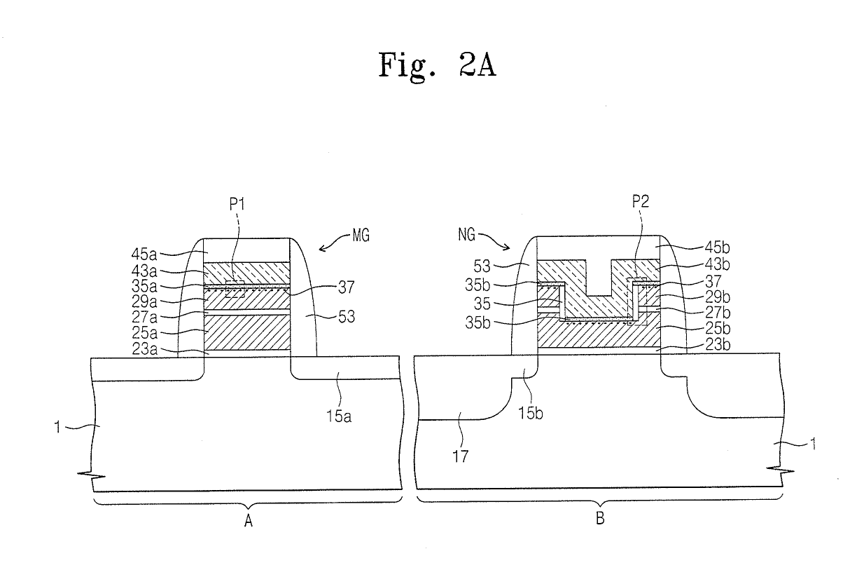

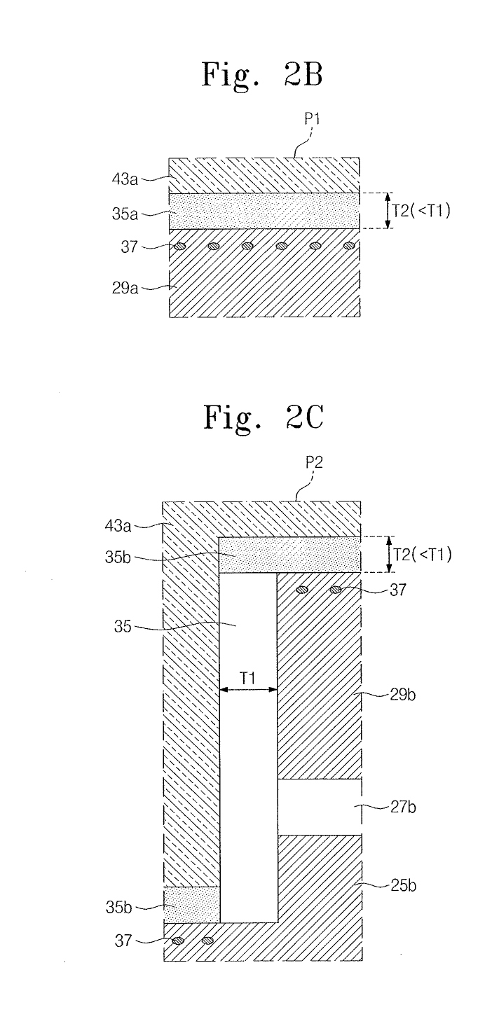

FIG. 2A illustrates a cross-sectional view of a semiconductor device according to an embodiment. FIGS. 2B and 2C illustrate enlarged views of a portion P1 and a portion P2 of FIG. 2A, respectively.

Referring to FIGS. 2A, 2B, and 2C, a first gate pattern MG and a second gate pattern NG may be disposed in a first region A and a second region B of a substrate 1, respectively, in a semiconductor device according to an embodiment. The first region A may be a cell array region. The second region B may be a peripheral region or a region of a cell array region that does not need a memory function. The first gate pattern MG may be a gate pattern performing a memory function. The second gate pattern NG may be a non-memory gate pattern that does not perform a memory function.

The first gate pattern MG may include a tunnel insulating layer 23a, a first lower poly-silicon pattern 25a, a first blocking insulating layer 27a, a first upper poly-silicon pattern 29a, a first interface pattern 35a, a first metal pattern 43a, and a first capping pattern 45a, which may be sequentially stacked. The tunnel insulating layer 23a, the first lower poly-silicon pattern 25a, the first blocking insulating layer 27a, the first upper poly-silicon pattern 29a, the first interface pattern 35a, and the first metal pattern 43a may have widths that are equal/similar to (e.g., substantially the same as) each other and sidewalls aligned with each other, respectively.

The second gate pattern NG may include a gate insulating layer 23b, a second lower poly-silicon pattern 25b, a second blocking insulating layer 27b, a second upper poly-silicon pattern 29b, a second interface pattern 35b, a second metal pattern 43b, and a second capping pattern 45b, which may be sequentially stacked. The second metal pattern 43b may successively penetrate the second interface pattern 35b, the second upper poly-silicon pattern 29b, and the second blocking insulating layer 27b, and thus may be adjacent to a top surface of the second lower poly-silicon pattern 25b. The second interface pattern 35b may also be disposed between the top surface of the poly-silicon pattern 25b and the second metal pattern 35b. An amorphous layer 35 may be disposed between a sidewall of the second upper poly-silicon pattern 29b and the second metal pattern 43b. The amorphous layer 35 may extend to be disposed between a sidewall of the second blocking insulating layer 27b and the second metal pattern 43b.

Metal silicide particles 37 may be discontinuous from each other and may be disposed under the first interface pattern 35a and may be adjacent to a top surface of the first upper poly-silicon pattern 29a (e.g., disposed in the first upper poly-silicon pattern 29a). The metal silicide particles 37 may also be disposed to be adjacent to a top surface of the second upper poly-silicon pattern 29b and the top surface of the second lower poly-silicon pattern 25b under the second interface pattern 35b (e.g., disposed in the second upper poly-silicon pattern 29b and the second lower poly-silicon pattern 25b under the second interface pattern 35b). However, as illustrated in FIG. 2A, the metal silicide particles 37 may not be disposed to be adjacent to the sidewall of the second upper poly-silicon pattern 29b adjacent to the amorphous layer 35.

A thickness T2 of the first interface pattern 35a may be substantially equal to a thickness T2 of the second interface pattern 35b (where the thickness T2 may be in a vertical direction). The thickness T2 of each of the first and second interface patterns 35a and 35b may be smaller than a width T1 (or a thickness in a horizontal direction) of the amorphous layer 35.

The first lower poly-silicon pattern 25a may function as a floating gate. The poly-silicon patterns 25a, 25b, 29a, and 29b may be doped with N-type dopants or P-type dopants.

The interface patterns 35a and 35b may be formed of at least one of a metal-silicon oxide layer, a metal-silicon nitride layer, and a metal-silicon oxynitride layer. The interface patterns 35a and 35b may be formed by providing a metal into an amorphous layer (which may include, e.g., a silicon oxide layer, a silicon nitride layer, and/or a silicon oxynitride layer). The metal in the interface patterns 35a and 35b may be the same as the metal constituting the metal patterns 43a and 43b. The thickness of each of the first and second interface patterns 35a and 35b may be within a range of about 1 Å to about 100 Å, or a range of about 5 Å to about 40 Å.

The metal patterns 43a and 43b may include a metal such as, e.g., tungsten, aluminum, titanium, nickel, cobalt, and/or copper, and the like. The metal patterns 43a and 43b may be disposed on the interface patterns 35a and 34b of an amorphous state, respectively, and thus a crystal grain size of each of the metal patterns 43a and 43b may be relatively increased. In more detail, the crystal grain size of each of the metal patterns 43a and 43b may be equal to or greater than about 200 nm, or equal to or greater than 350 nm. Each of the metal patterns 43a and 43b may have a body centered cubic structure. A ratio of a surface density of a (110) plane to a surface density of a (200) plane [(110)/(200)] may be equal to or greater than 200, or equal to or greater than 240 in the body centered cubic structure of each of the metal patterns 43a and 43b. As described above, the crystal grain size of each of the metal patterns 43a and 43b may be increased, and thus a resistivity of the metal patterns 43a and 43b may be decreased. Thus, signal transmission speeds of the semiconductor device including the first gate pattern MG and the second gate pattern NG in both of the first region A and the second region B may be increased.

Each of the interface patterns 35a and 35b may function as a diffusion preventing layer that substantially prevents (and/or reduces the possibility of) reaction between each of the metal patterns 43a and 43b and each of the upper poly-silicon patterns 29a and 29b. Additionally, each of the interface patterns 35a and 35b may function as an ohmic layer between each of the upper poly-silicon patterns 29a and 29b and each of the metal patterns 43a and 43b. Thus, an interface resistance between each of the metal patterns 43a and 43b and each of the upper poly-silicon patterns 29a and 29b may be reduced. As a result, the signal transmission speed of the semiconductor device may be improved.

A width of the second gate pattern NG may be greater than a width of the first gate pattern MG. A spacer 53 may cover each of the sidewalls of the first and second gate patterns MG and NG. A first dopant injection region 15a (e.g., a low concentration dopant injection region) may be disposed in the substrate 1 adjacent to the first gate pattern MG, and a second dopant injection region 15b (e.g., a low concentration dopant injection region) and a third dopant injection region 17 (e.g., a high concentration dopant injection region) may be disposed in the substrate 1 adjacent to the second gate pattern NG.

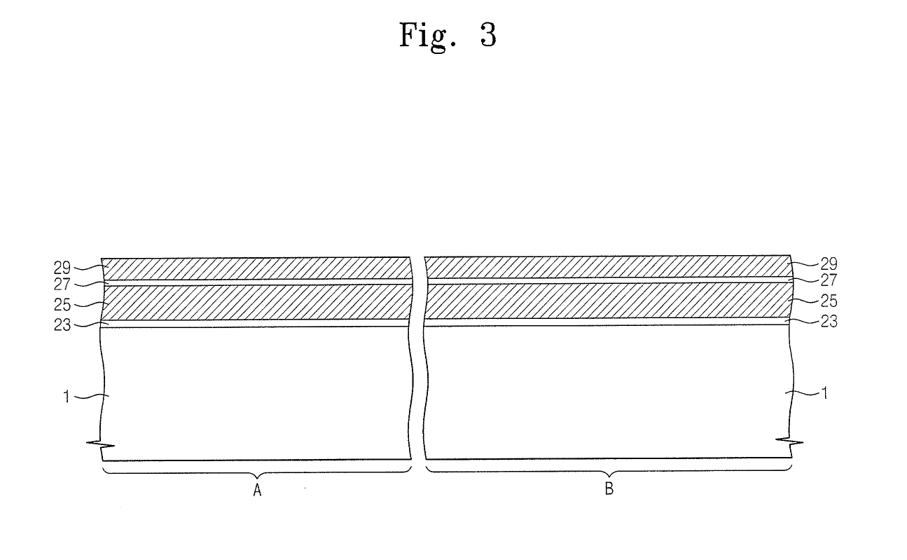

FIGS. 3 to 9 illustrate cross-sectional views of exemplary stages in a method of fabricating the semiconductor device of FIG. 2A, according to an embodiment.

Referring to FIG. 3, a thermal oxide layer 23, a lower poly-silicon layer 25, a blocking insulating layer 27, and an upper poly-silicon layer 29 may be sequentially stacked on an entire surface of a substrate 1 including a first region A and a second region B. Each of the lower poly-silicon layer 25 and the upper poly-silicon layer 29 may be doped with dopants. The blocking insulating layer 27 may be formed of a silicon oxide layer, an oxide-nitride-oxide (ONO) layer, and/or a high-k dielectric layer, and the like.

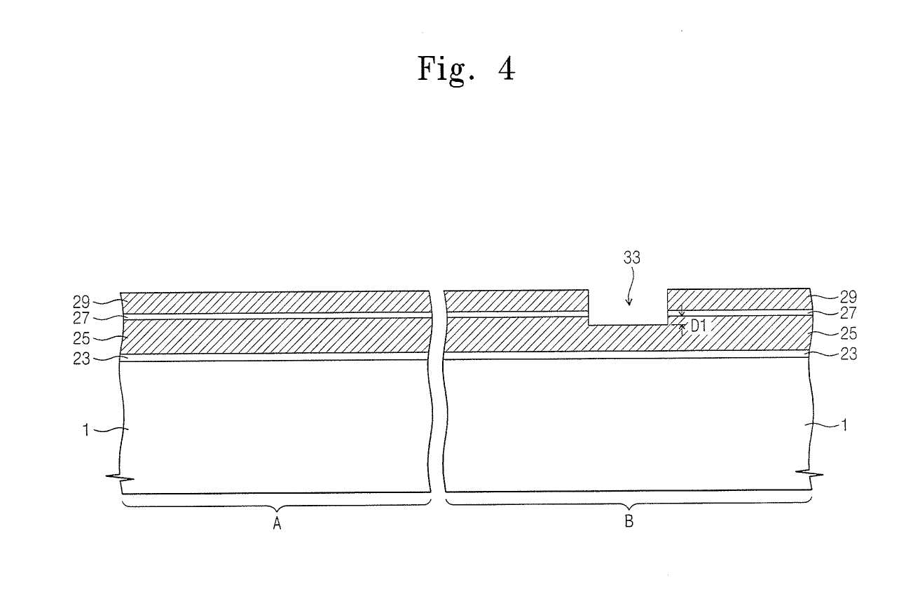

Referring to FIG. 4, the upper poly-silicon layer 29 and the blocking insulating layer 27 in the second region B may be patterned to form a butting region 33 (e.g., a gap) exposing the lower poly-silicon layer 25. A bottom surface of the butting region 33 may be recessed from a bottom surface of the blocking insulating layer 27 by a first depth D1. The first depth D1 may be, e.g., about 15 nm.

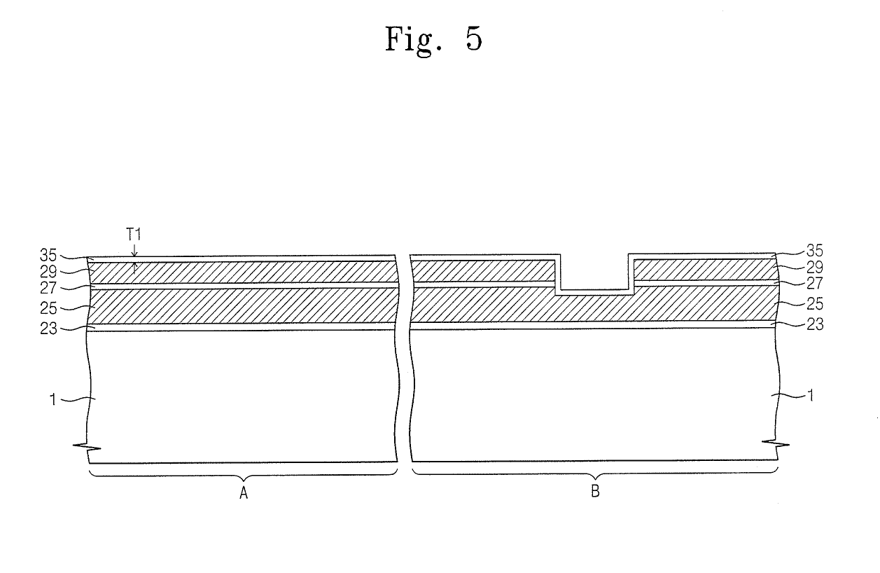

Referring to FIG. 5, an amorphous layer 35 may be conformally formed on an entire surface of the substrate 1. The amorphous layer 35 may be formed by a deposition process such as, e.g., a chemical vapor deposition (CVD) process or an atomic layer deposition (ALD) process. Alternatively, exposed surfaces of the lower poly-silicon layer 25 and the upper poly-silicon layer 29 may be oxidized and/or nitridized to form the amorphous layer 35. A wet cleaning process may be performed for oxidizing and/or nitridizing the exposed surfaces of the lower poly-silicon layer 25 and the upper poly-silicon layer 29. In other embodiments, oxygen ions and/or nitrogen ions may be injected into the exposed surfaces of the lower poly-silicon layer 25 and the upper poly-silicon layer 29 to form the amorphous layer 35. In still other embodiments, an annealing process may be performed on the exposed surfaces of the lower poly-silicon layer 25 and the upper poly-silicon layer 29 under a gas atmosphere including nitrogen, hydrogen, and/or oxygen. In this case, ammonia (NH₃) may be used as the gate including nitrogen. The amorphous layer 35 may be formed to be in contact with the lower poly-silicon layer 25 and the upper poly-silicon layer 29. For example, the amorphous layer 35 may be formed of at least one of a silicon oxide layer, a silicon nitride layer, and a silicon oxynitride layer. The amorphous layer 35 may be single-layered or multi-layered. The amorphous layer 35 may have a first thickness T1. The first thickness T1 may be within a range of about 1 Å to about 100 Å, or about 5 Å to about 40 Å.

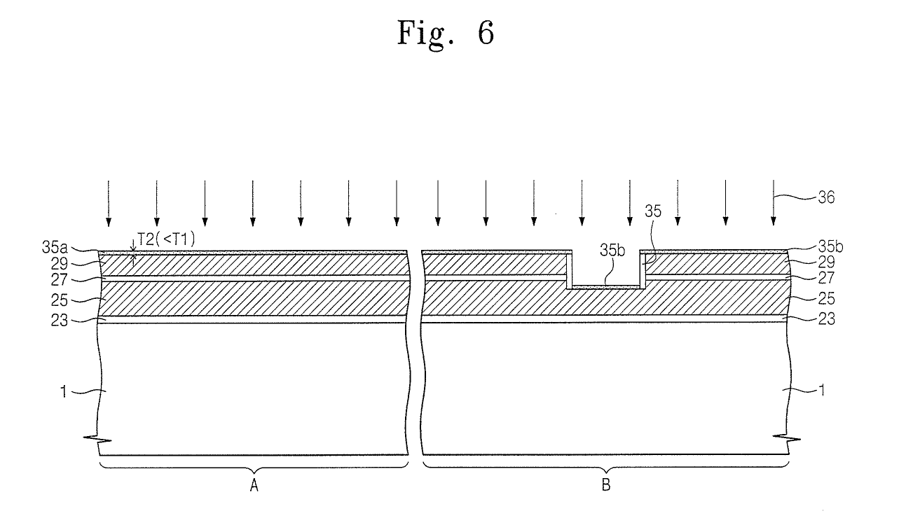

Referring to FIG. 6, a metal element may be converted to into a metal plasma 36 state and then a bias may be applied to the metal plasma 36 to permeate metal element ions of the metal plasma 36 into the amorphous layer 35. Thus, the amorphous layer 35 may be permeated with the metal element ions and may be converted into interface layers 35a and 35b. The metal element ions may have a straightness property (e.g., the metal element ions may be permeated substantially vertically), and thus the metal element ions may be permeated into only the amorphous layer 35 adjacent to the exposed top surfaces of the poly-silicon layers 25 and 29 (i.e., the horizontal portions of the amorphous layer 35). Thus, the metal element ions may not be permeated into the amorphous layer 35 adjacent to exposed sidewalls of the poly-silicon layers 25 and 29 (i.e., the vertical portions of the amorphous layer 35). As a result, the amorphous layer 35 adjacent to the exposed sidewalls of the poly-silicon layers 25 and 29 may not be converted into the interface layers 35a and 35b and may remain as the amorphous layer 35. The amount of the metal plasma 36 and/or a voltage of the bias may be suitably controlled to control a content ratio of the metal included in the interface layers 35a and 35b. The surface of the amorphous layer 35 through which the metal plasma 36 is permeated may be damaged by the metal plasma 36. Thus, a second thickness T2 of each of the interface layers 35a and 35b may be smaller than the first thickness T1 of the amorphous layer 35. The second thickness T2 of each of the interface layers 35a and 35b may be controlled by the first thickness T1 of the amorphous layer 35, the amount of the metal plasma 36, and/or the voltage of the bias. The metal content and the thickness of the interface layers 35a and 35b may be controlled to adjust the electrical characteristics of the interface layers 35a and 35b. The metal element may include at least one of tungsten, aluminum, titanium, nickel, cobalt, and/or copper, and the like. The metal element may be tungsten.

In an embodiment, the amorphous layer 35 may a double layer of a silicon oxide layer and a silicon nitride layer. The double layer structure of the amorphous layer 35 may be broken (e.g., converted) by the metal plasma 36, and thus a single-layered metal silicon oxynitride layer may be formed as the interface layer 35a and 35b. A thickness of each of the silicon oxide layer and the silicon nitride layer of the double layer may be within a range of about 1 Å to about 30 Å.

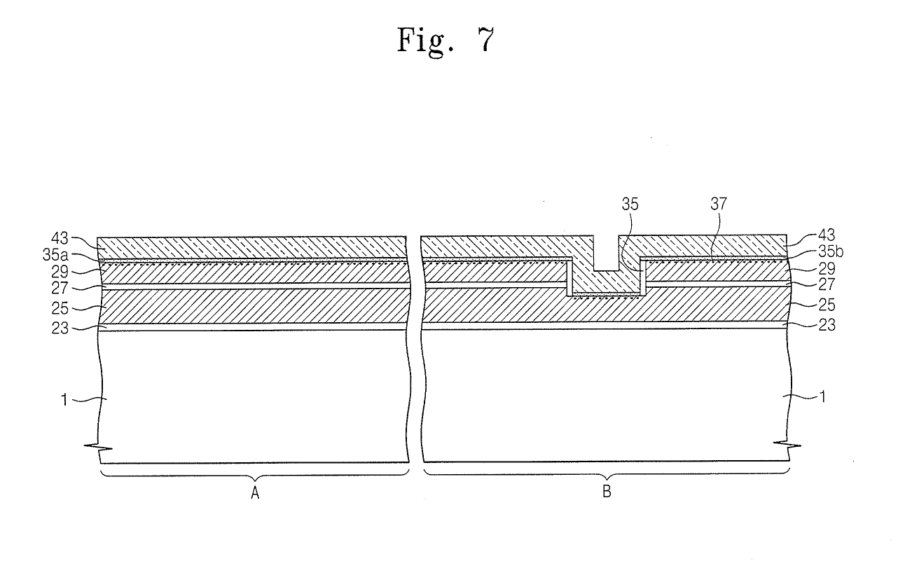

Referring to FIG. 7, a metal layer 43 may be formed on the interface layers 35a and 35b. The metal plasma 36 treatment may be continuously performed in the state that the bias is applied, thereby depositing the metal layer 43 (i.e., the same metal plasma 36 treatment may be used to form the interface layers 35a and 35b and the metal layer 43). And then a thermal treatment process may be performed to combine the metal included (or injected) in the interface layer 35a and 35b with the amorphous layer within the interface layers 35a and 35b (i.e., the metal may be combined with the amorphous material, e.g., silicon oxide, silicon nitride, and/or silicon oxynitride, in the interface layer 35a and 35b). Thus, the damage within the interface layers 35a and 35b may be cured. Additionally, the metal layer 43 may be crystallized by the thermal treatment process. At this time, the metal layer 43 may be formed on the interface layers 35a and 35b of the amorphous state, and thus a crystal grain size of the metal layer 43 may increase, and the metal layer 43 may have a low resistivity.

At this time, the metal grain size of the metal layer 43 may be equal to or greater than about 200 nm, or equal to or greater than 350 nm. The metal layer 43 may have a body centered cubic structure. A ratio of a surface density of a (110) plane to a surface density of a (200) plane [(110)/(200)] may be equal to or greater than 200, or equal to or greater than 240 in the body centered cubic structure of the metal layer 43. A small amount of the metal included in the interface layers 35a and 35b may be diffused by the thermal treatment process to form discontinuous metal silicide particles 37 adjacent to top surfaces of the upper and lower poly-silicon layers 29 and 25 under the interface layers 35a and 35b (e.g., disposed in the upper and lower poly-silicon layers 29 and 25 under the interface layers 35a and 35b). The metal silicide particles 37 may be disposed in island-shapes isolated from each other, and thus the metal silicide particles 37 may not constitute a continuous layer.

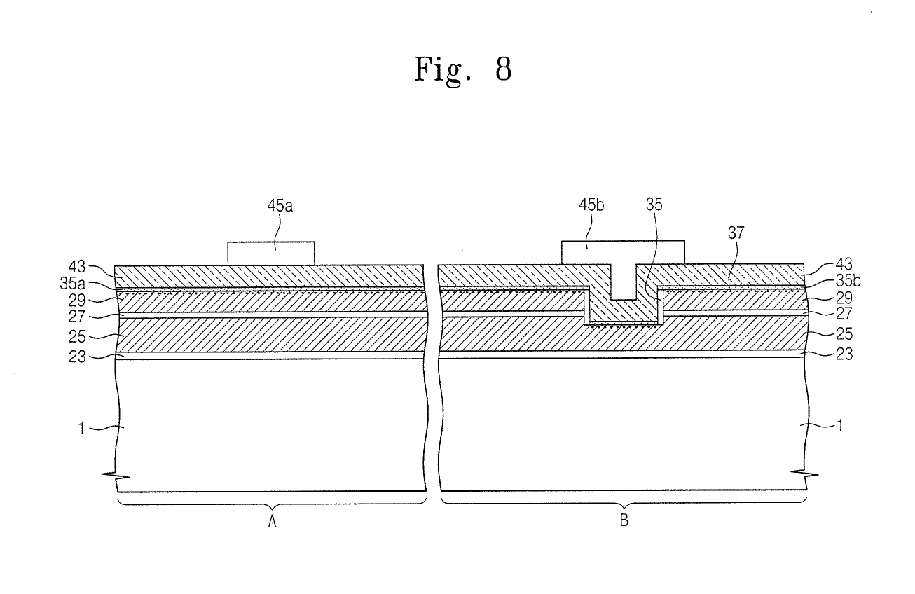

Referring to FIG. 8, a first capping pattern 45a and a second capping pattern 45b may be formed on the metal layer 43 in the first region A and the second region B, respectively.

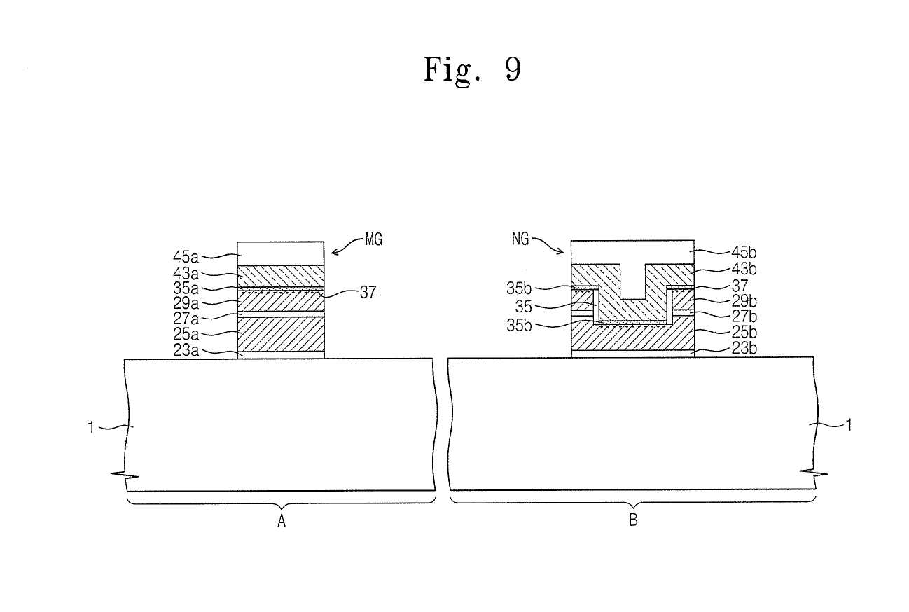

Referring to FIG. 9, underlying layers may be sequentially patterned using the first and second capping patterns 45a and 45b as etch masks to form a first gate pattern MG in the first region A and a second gate pattern NG in the second region B. The first gate pattern MG may include a tunnel insulating layer 23a, a first lower poly-silicon pattern 25a, a first blocking insulating layer 27a, a first upper poly-silicon pattern 29a, a first interface pattern 35a, a first metal pattern 43a, and a first capping pattern 45a, which may be sequentially stacked. The second gate pattern NG may include a gate insulating layer 23b, a second lower poly-silicon pattern 25b, a second blocking insulating layer 27b, a second upper poly-silicon pattern 29b, a second interface pattern 35b, a second metal pattern 43b, and a second capping pattern 45b, which may be sequentially stacked. The interface layers 35a and 35b may function as etch stop layers in the patterning process.

Subsequently, referring to FIG. 2A, a spacer 53 may be formed to cover a sidewall of each of the first and second gate patterns MG and NG. Dopant injection regions 15a, 15b, and 17 may be formed in the substrate 1 adjacent to the gate patterns NG and MG.

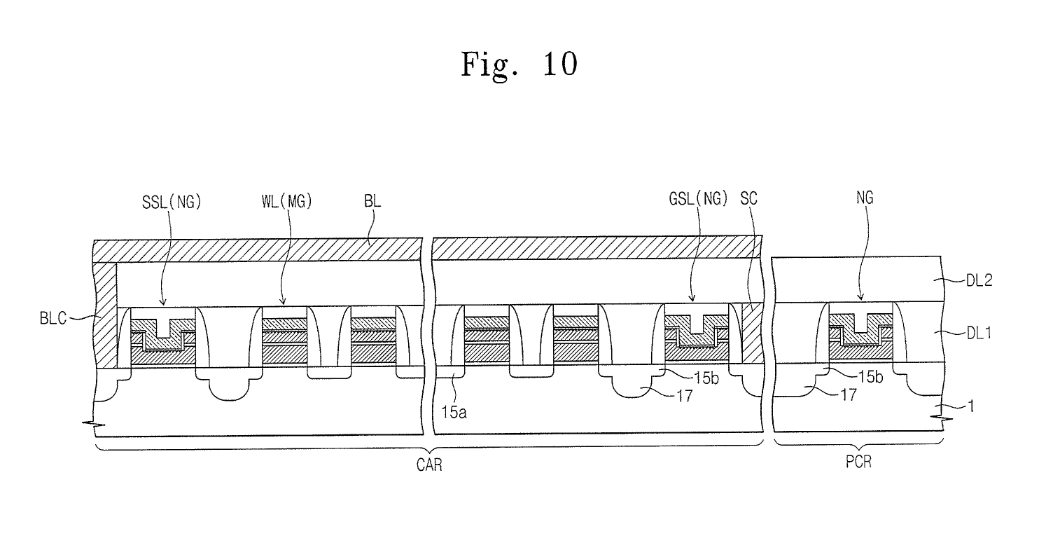

FIG. 10 illustrates a cross-sectional view of a non-volatile memory device according to an embodiment. Referring to FIG. 10, the non-volatile memory device may be, e.g., a flash memory device. The non-volatile memory device may include a substrate 1 including a cell array region CAR and a peripheral circuit region PCR. A ground selection line GSL, a string selection line SSL parallel to the ground selection line GSL, and a plurality of word lines WL disposed between the ground and string selection lines GSL and SSL may be disposed in the cell array region CAR. The lines GSL, SSL, and WL may extend in one direction and be spaced apart from each other to be parallel to each other. The ground selection line GSL, the string selection line SSL, and the word lines WL may constitute a cell string. The cell string may be symmetrically and repeatedly disposed in the cell array region CAR. The word line WL may have the same structure as the first gate pattern MG described with reference to FIG. 2A. Each of the ground and string selection lines GSL and SSL may have the same structure as, for example, the second gate pattern NG described with reference to FIG. 2A.

The second gate pattern NG may be disposed in the peripheral circuit region PCR. Dopant injection regions 15a, 15b, and 17 may be disposed in the substrate 1 adjacent to gate patterns NG and MG. Gap regions between the gate patterns NG and MG may be filled with a first interlayer insulating layer DL1. A common source line SC may be disposed on the dopant injection region 15b and 17 adjacent to the ground selection line GSL. A bit line contact BLC may be disposed on the dopant injection region 15b and 17 adjacent to the string selection line SSL. A second interlayer insulating layer DL2 may be disposed on the first interlayer insulating layer DL1, and a bit line BL may be disposed on the second interlayer insulating layer DL2. The bit line BL may be electrically connected to the bit line contact BLC. The bit line BL may extend in a direction crossing the word line WL. A method for fabricating the non-volatile memory device may include the same/similar fabricating method described with reference to FIGS. 3 to 9.

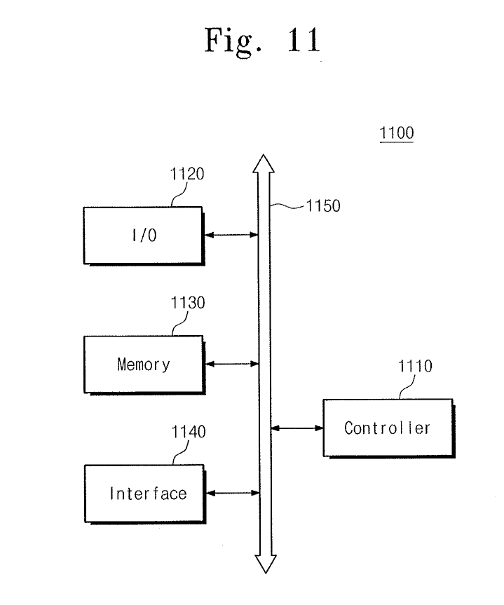

FIG. 11 illustrates a schematic block diagram of an exemplary memory system including a semiconductor device according to an embodiment. Referring to FIG. 11, the electronic system 1100 may be applied to, e.g., a personal digital assistant (PDA), a portable computer, a web tablet, a wireless phone, a mobile phone, a digital music player, a memory card, and/or other electronic products. The other electronic products may receive or transmit wireless information data.

The electronic system 1100 may include a controller 1110, an input/output (I/O) unit 1120, a memory device 1130, an interface unit 1140, and a data bus 1150. At least two of the controller 1110, the I/O unit 1120, the memory device 1130, and the interface unit 1140 may communicate with each other through the data bus 1150.

The controller 1110 may include at least one of a microprocessor, a digital signal processor, a microcontroller, and/or other logic devices. The other logic devices may have a similar function to any one of the microprocessor, the digital signal processor, the microcontroller, and the like. The memory device 1130 may store commands performed by the controller 1110. The I/O unit 1120 may receive data or signal from the outside of the system 110 and/or transmit data or signal to the outside of the system 1100. For example, the I/O unit 1120 may include a keypad, a keyboard and/or a display unit.

The memory device 1130 may include the non-volatile memory device according to an embodiment. The memory device 1130 may further include at least one other kind of memory devices and/or non-volatile memory devices.

The interface unit 1140 may transmit data to a communication network and/or receive data from the communication network.

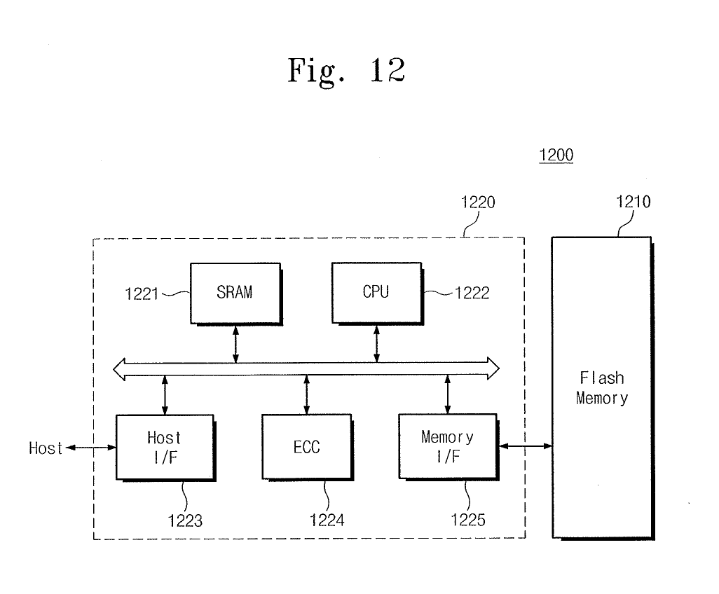

FIG. 12 illustrates a schematic block diagram of an exemplary memory card including a semiconductor device according to an embodiment.

Referring to FIG. 12, a memory card 1200 for storing data may include a flash memory device 1210 according to an embodiment. The memory card 1200 according to an embodiment may include a memory controller 1220 that controls data communication between a host and the memory device 1210.

An SRAM device 1221 may be used as an operation memory of a central processing unit (CPU) 1222. A host interface unit 1223 may be configured to include a data communication protocol of a host connected to the memory card 1200. An error check and correction (ECC) block 1224 may detect and correct errors of data which are read out from the memory device 1210. A memory interface unit 1225 may interface with the flash memory device 1210 according to an embodiment. The CPU 1222 may perform overall operations for data exchange of the memory controller 1220. Even though not shown in the drawings, the memory card 1200 may further include a read only memory (ROM) device that stores code data to interface with the host.

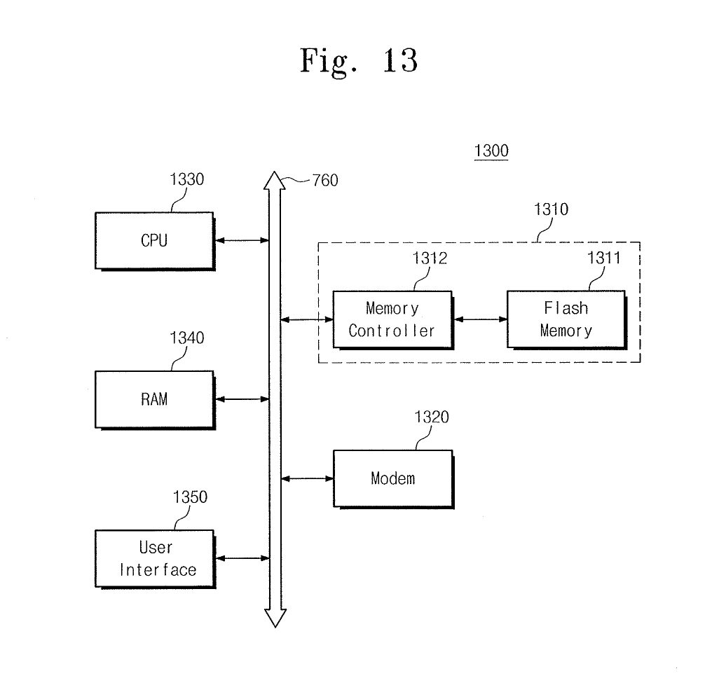

FIG. 13 illustrates a schematic block diagram of an exemplary information processing system including a semiconductor device according to an embodiment.

Referring to FIG. 13, an information processing system 1300 such as, e.g., a mobile device, a desk top computer, and/or the like, may include a flash memory system 1310 according to an embodiment. The information processing system 1300 according to an embodiment may include a modem 1320, a central processing unit (CPU) 1330, a RAM 1340, a user interface unit 1350 that are electrically connected the flash memory system 1310 through a system bus 1360. The flash memory system 1310 may be substantially the same as the aforementioned memory system or flash memory system. Data processed by the CPU 1330 or data inputted from an external system may be stored in the flash memory system 1310. The flash memory system 1310 may include a solid state disk (SSD). In this case, the information processing system 1300 may stably store large amounts of data in the flash memory system 1310. As reliability increases, the flash memory system 1310 may reduce a resource for correcting errors to allow the information processing system 1300 to perform a high speed data exchange function. Even though not shown in the drawings, the information processing system 1300 may further include an application chipset, a camera image processor (CIS), and/or an input/output unit, and the like.

The flash memory devices or the memory systems according to the embodiments described above may be encapsulated using a suitable packaging technique. For example, the flash memory devices or the memory systems according to an embodiment may be encapsulated using any one of, e.g., a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOIC) technique, a shrink small outline package (SSOP) technique, a thin small outline package (TSOP) technique, a thin quad flat package (TQFP) technique, a system in package (SIP) technique, a multi chip package (MCP) technique, a wafer-level fabricated package (WFP) technique, and a wafer-level processed stack package (WSP) technique, and the like.

By way of summation and review, the widths of word lines in non-volatile memory devices may be reduced to achieve high integration. Thus, it may be desirable to reduce a line resistance (or a sheet resistance) of the word line to improve a programming speed and/or a reading speed of the data storing pattern. Additionally, a gate electrode of the peripheral circuit may have a width wider than that of the word line and a length shorter than that of the word line. Thus, a line resistance (or a sheet resistance) of the gate electrode may not be as important a factor for influencing an operation speed of a peripheral circuit transistor.

As explained above, the gate electrode of the semiconductor device according to an embodiment may include the interface layer disposed between the poly-silicon pattern and the metal pattern. The interface layer may be formed by providing the metal into the amorphous layer. The metal pattern may be located on the interface layer of the amorphous state, and thus the crystal grain size of the metal pattern may be increased to provide decreased resistivity. Thus, the line/sheet resistance of the gate electrode may be reduced and the signal transmission speed may be improved. Additionally, the interface layer may function as the diffusion preventing layer that substantially prevents (and/or reduces the possibility of) the reaction between the metal pattern and the poly-silicon pattern. Furthermore, the interface layer may include the metal, and thus the interface layer may function as the ohmic layer between the poly-silicon pattern and the metal pattern. Thus, the interface resistance between the metal pattern and the poly-silicon pattern may be reduced.

The gate electrode including the interface layer according to an embodiment may be applied to the control gate (or the word line) of the memory cell disposed in the cell array region. The gate electrode including the interface layer may also be applied to the gate electrode of the non-memory cell disposed in the peripheral circuit region. Thus, the signal transmission speed of the semiconductor device may be improved by the gate electrode according to an embodiment.

In the method for fabricating the semiconductor device according to an embodiment, the metal element may be converted into the metal plasma and then the metal ions of the metal plasma may be permeated into the amorphous layer by applying bias, so that the interface layer may be formed. Further, the amount of the metal plasma may be controlled to control the content of the metal included in the interface layer, and to control the thickness of the interface layer. As a result, the electrical characteristics of the interface layer may be controlled.

In the method for fabricating the semiconductor device according to an embodiment, the metal layer may be formed of the interface layer, which may have an amorphous state, and thus the crystal grain size of the metal layer may be increased and the metal layer may have a reduced resistivity.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor device, comprising:
a substrate;
a first poly-silicon pattern on the substrate;
a metal pattern on the first poly-silicon pattern; and
an interface layer between the first poly-silicon pattern and the metal pattern,
wherein the interface layer includes at least one selected from the group of a metal-silicon oxynitride layer, a metal-silicon oxide layer, and a metal-silicon nitride layer.

2. The semiconductor device as claimed in claim 1, wherein a metal included in the interface layer is the same as a metal constituting the metal pattern.

3. The semiconductor device as claimed in claim 1, wherein:
a crystal grain size of the metal pattern is equal to greater than about 200 nm,
the metal pattern has a body centered cubic structure, and
a ratio of a surface density of a (110) plane to a surface density of a (200) plane in the body centered cubic structure is equal to or greater than about 200.

4. The semiconductor device as claimed in claim 1, further comprising:
a second poly-silicon pattern under the first poly-silicon pattern;
a blocking insulating layer between the second poly-silicon pattern and the first poly-silicon pattern; and
a tunnel insulating layer between the second poly-silicon pattern and the substrate.

5. The semiconductor device as claimed in claim 4, wherein:
the metal pattern penetrates at least the first poly-silicon pattern and the blocking insulating layer, such that the metal pattern is adjacent to the second poly-silicon pattern, and
the interface layer is:
between a top surface of the first poly-silicon pattern and the metal pattern, and
between a top surface of the second poly-silicon pattern and the metal pattern.

6. The semiconductor device as claimed in claim 5, further comprising:
an amorphous layer between a sidewall of the first poly-silicon pattern and the metal pattern, wherein the amorphous layer is not doped with a metal included in the interface layer.

7. The semiconductor device as claimed in claim 6, wherein a width of the amorphous layer is greater than a thickness of the interface layer.

8. The semiconductor device as claimed in claim 6, wherein the amorphous layer includes at least one selected from the group of a silicon nitride layer, a silicon oxide layer, and a silicon oxynitride layer.

9. The semiconductor device as claimed in claim 4, further comprising:
metal silicide particles adjacent to a top surface of the first poly-silicon pattern and to a top surface of the second poly-silicon pattern under the interface layer, wherein the metal silicide particles are discontinuous.

10-15. (canceled)

16. A semiconductor device, comprising:
a substrate having a first region and a second region;
a first lower poly-silicon pattern on the first region of the substrate;
a first blocking insulating layer on the first lower poly-silicon pattern;
a first upper poly-silicon pattern on the first blocking insulating layer;
a first interface layer on the first upper poly-silicon pattern, the first interface layer including at least one selected from the group of a metal-silicon oxynitride layer, a metal-silicon oxide layer, and a metal-silicon nitride layer;
a second lower poly-silicon pattern on the second region of the substrate;
a second blocking insulating layer on the second lower poly-silicon pattern;
a second upper poly-silicon pattern on the second blocking insulating layer;
a second interface layer on the second lower poly-silicon pattern and the second upper poly-silicon pattern, the second interface layer including at least one selected from the group of the metal-silicon oxynitride layer, the metal-silicon oxide layer, and the metal-silicon nitride layer;
wherein:
the first upper poly-silicon pattern is between all portions of the first interface layer and the first lower semiconductor pattern, and
the second interface layer includes a first portion and a second portion, the first portion of the second interface layer is on the second upper poly-silicon pattern, and the second portion of the second interface layer is directly on the second lower poly-silicon pattern.

17. The semiconductor device as claimed in claim 16, wherein:
the first lower poly-silicon pattern, the first blocking insulating layer, the first upper poly-silicon pattern, and the first interface layer on the first region are part of a memory cell, and
the second lower poly-silicon pattern, the second blocking insulating layer, the second upper poly-silicon patter, and the second interface layer on the second region are part of a non-memory cell.

18. The semiconductor device as claimed in claim 16, further comprising an amorphous layer in the second region, wherein:
the amorphous layer is between the first portion of the second interface layer and the second portion of the second interface layer, and
the amorphous layer does not include the metal-silicon oxynitride layer, the metal-silicon oxide layer, or the metal-silicon nitride layer.

19. The semiconductor device as claimed in claim 18, wherein:
the amorphous layer covers a sidewall of the second upper poly-silicon pattern and the second blocking insulating layer, and
a bottom surface of the second portion of the second interface layer is below a top surface of the second lower poly-silicon pattern.

20. The semiconductor device as claimed in claim 18, further comprising:
a first metal layer covering the first interface layer; and
a second metal layer covering:
the first portion of the second interface layer,
the second portion of the second interface layer, and
the amorphous layer.
